(19) United States
(12) Patent Application Publication
(10) Pub. No.: US 2003/0133264 A1
(43) Pub. Date: Jul. 17, 2003

(54) Heat sink

(76) Inventor: Damian Kerwin, Brisbane (AU)

Correspondence Address: REINHART BOERNER VAN DEUREN S.C., ATTN: LINDA GABRIEL, DOCKET COORDINATOR, 1000 NORTH WATER STREET, SUITE 2100, MILWAUKEE, WI, 53202, US

(21) Appl. No.: 10/308,359

(22) Filed: Dec. 3, 2002

(30) Foreign Application Priority Data
Dec. 4, 2001 (AU) PR9259

(51) Int. Cl. G06F 1/20; H05K 7/20

(52) U.S. Cl. 361/687; 361/697; 361/695

(57) ABSTRACT

A heat sink 1 for use with a central processor unit or microprocessor 10 is disclosed. The heat sink 1 comprises a body 2 having an outer surface facing to the exterior and a plurality of internal passages 5 and voids 8 and 9 defined therein, forming an internal surface. The body 2 has a first plurality of passages 5 extending in a first direction and a second plurality of passages 5 extending in a second direction substantially perpendicular to the first direction. The passages 5 intersect with each other and open out into each other and also open out on to the outer surface of the body. The body has two voids 8 and 9 that extend from the front or leading face 11 of the outer surface in one of the first and second directions inwardly into the body 2. Typically the voids 8 and 9 are arranged such that they are substantially perpendicular to each other to form a cross when the front or leading face 11 of the outer surface is viewed end on. The heat sink 1 also includes a fan 3 for drawing air through the passages 5 and the voids 8 and 9 in the body 2. Typically, the fan 3 is a low velocity fan having a speed of 2,000 to 5,000 rpm so as to reduce noise generated by the fan. The heat sink 1 is mounted on top of the microprocessor 10 where it assists in drawing excess heat away from the microprocessor 10. Typically this is required when a process called overclocking is engaged in by a computer enthusiast.

### CROSS-REFERENCE TO RELATED APPLICATION

This application claims priority of Australian provisional application number PR9259, which was filed on Dec. 4, 2001.

### BACKGROUND OF THE INVENTION

### FIELD OF THE INVENTION

This invention relates to a heat sink for heat transfer. It also extends to a central processing unit (CPU) including the heat sink.

This invention relates particularly, but not exclusively, to a heat sink for use with a CPU for a PC to assist in dissipating heat from the CPU and maintaining the temperature thereof within acceptable limits. It will therefore be convenient to hereinafter describe this invention with reference to this exemplary application. However it is to be clearly understood that the invention is capable of broader application. For example the heat sink may be applied to the dissipation of heat from any heat source in any application.

A CPU is a central component of a computer, e.g. a personal computer or a microprocessor controlled device.

During operation, current is passed through the silicon semiconductor device and this generates heat in the CPU which has to be dissipated. This is caused by the resistance to current flow through the silicon material. If the heat that is generated is not dissipated, the temperature of the silicon semiconductor increases progressively up to an avalanche point. The avalanche point is then followed by thermal runaway. When this happens the CPU is irreparably damaged.

As a result, CPU's are fitted by manufacturers with heat dissipation mechanisms so that the temperature is maintained within acceptable limits when they are operated according to specification. However, in some instances users operate CPU's outside of the manufacturer's specification. They want to garner more performance out of the CPU. This is known as overclocking and can be defined as a process by which more processing performance is extracted from a CPU than the specification specifies. The overclocking process takes advantage of a difference between the actual and stated potential of the CPU, and amounts to working the CPU harder. The practice of overclocking is widespread amongst PC users and particularly hobbyists who enjoy the challenge of pushing a component to its maximum.

However, the practice of overclocking generates additional heat in the microprocessor and the dissipation of this heat therefore needs to be managed. Typically this is accomplished by means of a heat sink having a fan mounted on the microprocessor. The fan blows air over the heat sink to transfer heat to the air and away from the device.

Well known heat sinks typically comprise a body having a plurality of heat transfer fins extending around the periphery thereof. The fins provide an increased surface area for the dissipation of heat. Each fin has a triangular configuration when viewed in cross-section.

Typically the heat sink is made by providing an underlying copper body and then brazing or spot welding each fin onto the copper body. It is not practical to machine or form the heat sink from a single body of copper. However the points of welding attachment of the fins to the body create a junction which can resist the flow of heat therethrough.

Some heat sinks comprise a body formed from aluminum, e.g. by extrusion, with copper fins mounted onto the aluminum body. FIG. 1a shows a known heat sink mounted on a microprocessor. FIG. 1b is a top plan view of the heat sink showing the fins.

Typically, fans that are used in these heat sinks are high velocity, high volume fans spinning at 6,000-7,000 rpm. They create an audible noise at a level of typically 42 dB. This noise is a major problem, as PC users typically require a quiet, peaceful environment when they are working on their computer. Many critical reviews in the literature on state of the prior art heat sinks confirm this problem. A familiar refrain in the reviews is “ . . . another great heat sink achieving some great results, but still we must persist with the noise of the high speed fans.”

One well known heat sink is the THERMALRIGHT 6B-6L HSF supplied by the company Thermalright.

Another well known heat sink is the ALPHA PAL 8045 sink supplied by Alpha Novatech.

The ALPHA PAL 8045 produces reasonable results. However it relies on a high velocity 80 mm fan which generates levels of noise similar to those described above. Other disadvantages include its physical size or surface area in contact with the motherboard. This size reduces the number of motherboards to which it can be attached. In addition, its mounting arrangement limits it to two types of motherboard manufacturers, namely ASUS and AOPEN boards. Another disadvantage is its substantial weight of 890 grams.

Clearly it would advantageous if a heat sink could be devised which at least partly overcame this limitation and which efficiently dissipated heat from the sink. The current patent application is focussed squarely on addressing this problem.

### SUMMARY OF THE INVENTION

The disadvantages and limitations of the background art discussed above are overcome by the present invention. According to one aspect of this invention there is provided a heat sink, e.g. for use with a CPU or microprocessor, the heat sink comprising two elements.

The first element is a body having an outer surface facing the exterior and a plurality of internal passages defined therein forming an internal surface.

The second element is a fan mounted on the body to displace air over the internal surface of the body, whereby heat is transferred from the body to air passing through the internal passages to cool the body and the associated central processing unit or microprocessor.

Thus, the surface of the body and in particular the internal surface lining the passages provides a large surface area for heat transfer and dissipation of heat.

Naturally, the body will be formed from a material having a high coefficient of thermal conductivity. Typically this may be a metal capable of being machined such as aluminum.

The body may have a plurality of passages extending in a first direction and a plurality of passages extending in a second direction substantially transverse to the first direction.

The passages in the first and second directions respectively may intersect with each other so as to open out into each other, and further the ends of the passages opening onto the outer surface of the body may be open. It will be appreciated that the design of the passages must admit the entry of air into the passages and the exit of air from the passages.

The passages may have a broadly circular cross-section or configuration although this is not essential. For example they could also have a rectangular cross-section. For machining reasons a circular cross-section is preferred.

In one particularly convenient form, the body is in the form of a block that has a broadly rectangular configuration. The passages extending in the first direction may extend between two opposed sides and the passages extending in the second direction may extend between a further two opposed sides that are substantially orthogonal to the first pair of opposed sides.

This way the body or block has intersecting passages extending in both horizontal and vertical directions.

The passages extending in the first direction, or horizontal direction, may be arranged in the form of an array when viewed end on. Typically, there will be at least twenty passages arranged in the form of an array or matrix. In a preferred form, there are at least eight passages extending in each of two dimensions giving a total of at least sixty-four passages in the first direction.

The passages extending in the second direction, or vertical direction, may also be as described immediately above with respect to the passages extending in the first direction.

The passages may also extend substantially fully along the length of the body. The passages may have a diameter of approximately 3-6 mm.

The body may also define a void therein which is free of body material and through which air is free to flow. The difference between a void and a passage is that a void is much larger than a passage.

The void may extend lengthwise, e.g. in a direction parallel to the passages extending in the first direction, and at least one end of the void opens to the exterior, e.g. the front or leading end of the body. The void may extend a substantial length of the body, but not the full length of the body, as it is necessary for the material of the body to mechanically support the body. Thus, unlike the passages which extend in two dimensions, the void only extends in one dimension.

The void may be in the form of a slot, e.g. extending diametrically across the width or height of the body. Each slot may have a width of 1-20 mm, preferably 4-13 mm, e.g. about 8-10 mm.

In a preferred form, the void is in the form of two slots, each extending diagonally across the body from one corner to the other corner, to form a cross when viewed end on.

The void only extends lengthwise in one direction as distinct from the passages which extend in two directions or two dimensions.

The voids assist in achieving a suitably high volumetric flow rate of air through the body and in transferring heat away from the CPU.

Applicant has discovered that the combination of intersecting vertical and horizontal passages as described above, and at least one void as described above, is very efficacious in removing heat from the CPU.

Typically the fan may be a low velocity fan, e.g. the blade of the fan has a velocity significantly lower than for the fans used in typical prior art heat sinks. This results in the fans generating substantially less noise than the fans used in prior art heat sinks.

The passageways and the void may be machined in the body or block, e.g. using a computer numerical control (CNC) machine. The body or block with voids and passages defined therein is formed from a single integral piece of material, e.g. that has been machined.

This invention also extends to a microprocessor in combination with a heat sink as defined above with reference to the first aspect of the invention.

The heat sink may include any one or more of the preferred features of the invention as described above with reference to the first aspect.

The invention also extends to a computer including a CPU and a heat sink as described above according to the first aspect of the invention.

Again the heat sink may include any one or more of the preferred features described.

Finally, all of the aforesaid advantages and objectives are achieved without incurring any substantial relative disadvantage.

### DESCRIPTION OF THE DRAWINGS

These and other advantages of the present invention are best understood with reference to the drawings, in which:

FIG. 1a is a schematic three dimensional view of a known heat sink mounted on a CPU and motherboard; FIG. 1b is a schematic top plan view of the heat sink illustrated in FIG. 1;

FIG. 2 is a front view of a heat sink in accordance of one embodiment of the invention;

FIG. 3 is a top plan view of the heat sink illustrated in FIG. 2, with the fan removed for clarity;

FIG. 4 is a front plan view of a heat sink in accordance with the invention that is a minor variation on the heat sink illustrated in FIGS. 2 and 3;

FIG. 5 is a top plan views of the heat sink illustrated in FIG. 4, with the fan removed for clarity;

FIG. 6 is a three dimensional view of a microprocessor sitting in a processor socket;

FIG. 7 is a three dimensional view of a heat sink in accordance with one embodiment of the invention mounted in position on the microprocessor illustrated in FIG. 6; and

FIG. 8 is a three dimensional view of a heat sink in accordance with another embodiment of the invention mounted on the microprocessor illustrated in FIG. 6.

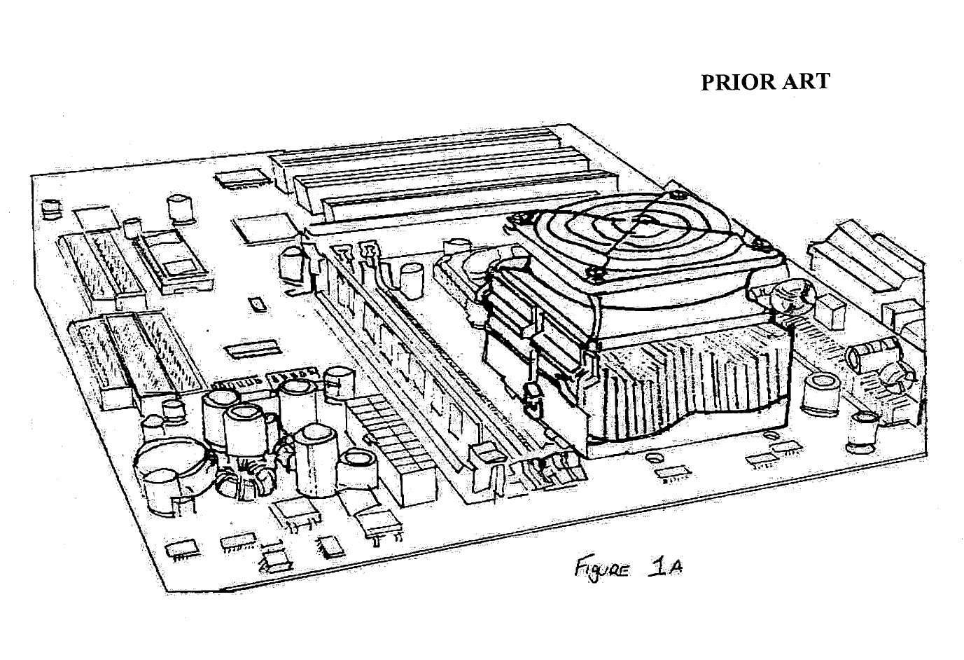

### DETAILED DESCRIPTION OF THE PREFERRED EMBODIMENT

A heat sink in accordance with the invention may manifest itself in a variety of forms. It will be convenient to hereinafter describe in detail two preferred embodiments of the invention with reference to the accompanying drawings. The purpose of providing this detailed description is to instruct persons having an interest in the subject matter of the invention how to carry the invention into practical effect. It is to be clearly understood however that the specific nature of this detailed description does not supersede the generality of the preceding broad description.

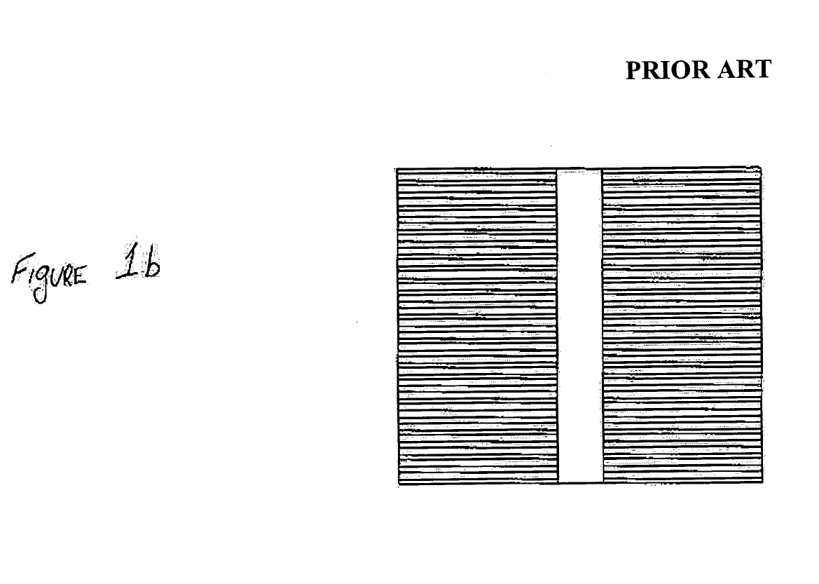

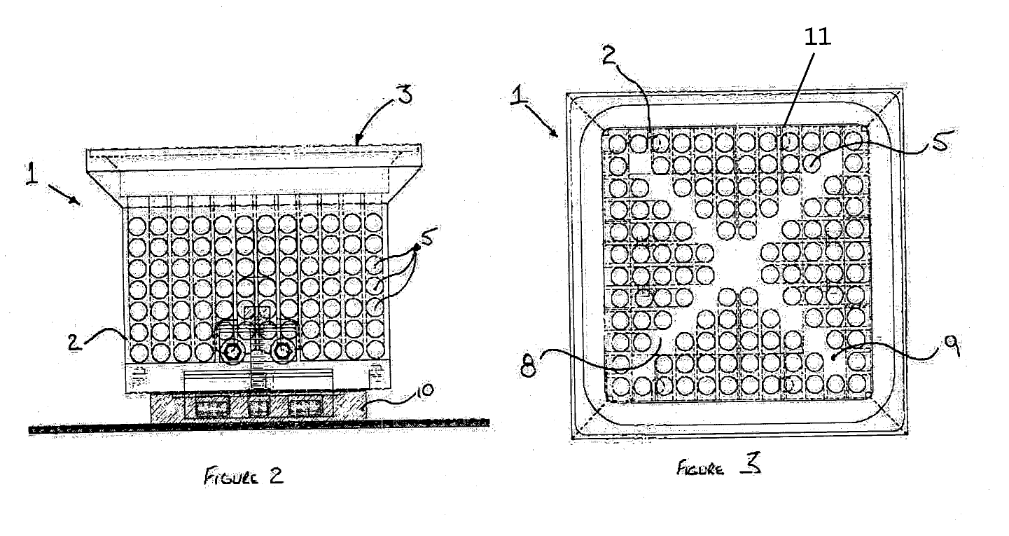

In FIGS. 2 and 3 reference numeral 1 refers generally to a heat sink in accordance with the invention.

The heat sink 1 comprises broadly a body 2 and a fan 3 mounted onto the body 2.

The body 2 comprises a square rectangular block of heat-conductive material, e.g. aluminum. The body 2 has a number of passages 5 defined therein and also has two voids 8 and 9 defined therein. The passages 5 and the voids 8 and 9 are machined into the block of aluminum forming the body 2.

The passages 5 comprise an array of small linear passages of substantially circular cylindrical configuration extending in a horizontal direction and a further array of similar circular cylindrical passages 5 extending in a vertical direction. Each end of each passage is open such that air can flow into and out of the passage. The horizontal and vertical passages 5 interconnect with each other to provide communication and therefore air flow therebetween.

The passages 5 have a diameter of approximately 3-6 mm and the voids 8 and 9 have a width of approximately 4-13 mm.

The body 2 may be formed by machining a block of aluminum metal. The passages may be formed by means of a computer numerically control (CNC) machine.

The two voids 8 and 9 define two slots extending generally from the front or leading face 11 of the body 2 towards the rear thereof. One void 8 extends diagonally across the front or leading face 11 between two diagonally opposed corners thereof. The other void 9 extends between the other two diagonally opposed corners when viewed end on. Thus the two voids 8 and 9 together form a cross when viewed end on. Each of the voids 8 and 9 runs lengthwise from the front or leading face 11 of the body 2 in a direction towards the rear of the body 2, but terminates short of the rear of the body 2. The voids 8 and 9 run at least halfway through the body 2.

The vertical passages 5 intersecting with the voids 8 and 9 open into the voids 8 and 9 to permit air flow from the passages 5 into the voids 8 and 9 and vice versa.

The fan 3 is mounted on the front or leading face 11 of the body 2 which is shown as facing upwardly in the drawings. The heat sink 1 includes a fan cowling and optionally also bodywork around the body 2 to both support the fan 3 and direct air displaced by the fan 3 into the voids 8 and 9 and the passages 5. Typically the fan 3 is a low velocity fan having a speed of approximately 2,000 to 5,000 rpm, and most typically 3,000 to 4,000 rpm, which has the effect of reducing the noise made by the fan 3.

Overall the heat sink 1 is mounted on the microprocessor 10 and the motherboard (not shown in FIGS. 2 or 3) in the manner indicated in FIG. 2 of the drawings.

In use, heat generated by the CPU is transferred to the body 2 by heat conduction transfer. The fan 3 then moves air through the passages 5 and the voids 8 and 9 to assist in removing heat from the block 2 by convection heat transfer.

The large surface area formed by these passages 5 enables a large amount of heat to be removed using a low volume fan operating at low velocity. The amount of heat that can be transferred away from the heat sink 1 is directly proportional to the surface area exposed to heat transfer. Further, the relative dimensions of the voids 8 and 9 and the passages 5 enables the relatively free flow of air therethrough without much frictional resistance or pressure drop. They provide an easy route for the flow of air from the passages 5 deep inside the body 2 to the outside surface of the body 2 to enable this air to flow out of the body 2.

The heat sink 1 is able to remove 100 joules of heat per second.

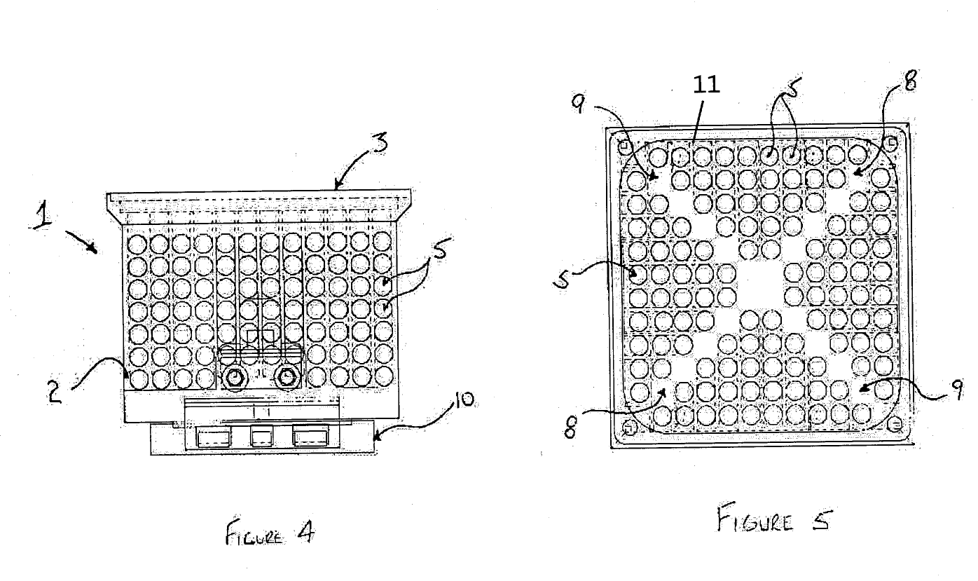

FIGS. 4 and 5 illustrate an embodiment which is very similar to the embodiment of FIGS. 2 and 3. The major difference is that the dimensions are smaller than those in the embodiment of FIGS. 2 and 3. Unless otherwise indicated, the same reference numerals used in FIGS. 2 and 3 are used to refer to the same components in FIGS. 4 and 5.

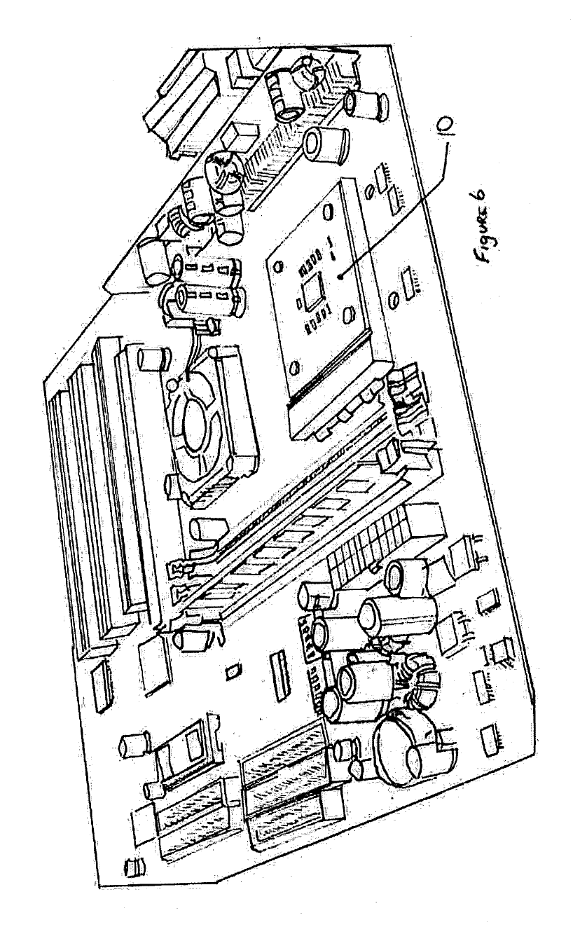

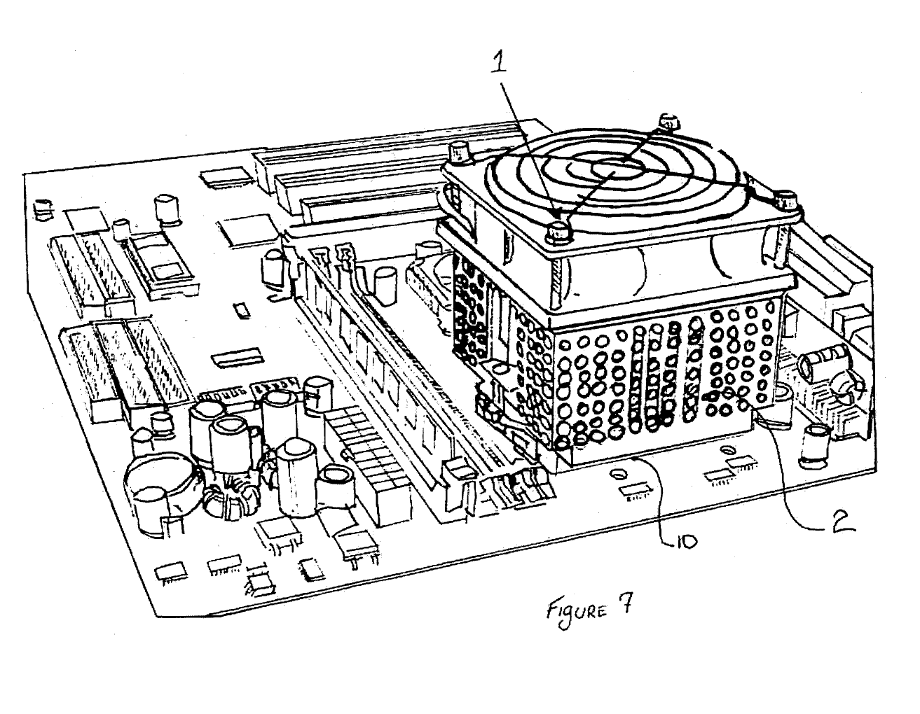

FIGS. 6 and 7 show the relative orientation of the motherboard, the microprocessor 10, and the heat sink 1 that is mounted on the microprocessor 10.

The rear face of the sink 1 is mounted on the top face of the microprocessor 10, with the fan 3 in turn mounted on the front or leading face 11 of the sink body 2, accordingly being spaced away from the microprocessor 10.

In use, heat generated by the CPU is transferred to the body 2 by heat conduction. The fan 3 then blows air through the passages 5 and the voids 8 and 9 of the body 2 to assist in removing heat from the body 2 by convection heat transfer.

FIG. 8 illustrates a larger heat sink 1 in accordance with the invention. The body 2 and the fan 3 have noticeably larger dimensions than those of the embodiment illustrated in FIG. 7. Otherwise the structure and functioning of this embodiment is very similar to that described above.

An advantage of the heat sink 1 described above with reference to the drawings is that the combination of passages 5 and voids 8 and 9 provides a large internal surface area for heat transfer within a unit volume, as well as the free flow of air therethrough to remove relatively large quantities of heat from the heat sink 1. The passages 5 and the voids 8 and 9 provide a network of conduits that is particularly favorable to fluid flow therethrough, much like a circulation system with arteries and arterioles in a human being. This enables a low volume, low velocity fan 3 to be used to efficaciously remove the heat from the microprocessor 10 and such a fan 3 will not give rise to the noise problems associated with many prior art heat sink/fan combinations. Further as the body 2 is formed from a single block of material that has been machined, there are no welds to resist heat transfer through the metal of the body 2.

By machining the passages 5 out of the block forming the body 2, the applicant has been able to create both horizontal and vertical passages that intersect with each other, which was not possible with the fins of prior art heat sinks. This enhances heat transfer and heat dissipation from the body 2.

It will of course be realized that the above has been given only by way of illustrative example of the invention, and that all such modifications and variations thereto as would be apparent to persons skilled in the art are deemed to fall within the broad scope and ambit of the invention as is herein set forth.

What is claimed is:

1. A heat sink for use with a central processing unit or microprocessor, the heat sink comprising:
a body having an outer surface facing the exterior and a plurality of internal passages defined therein forming an internal surface; and
a fan mounted on said body to displace air over the internal surface of said body, whereby heat is transferred from said body to air passing through said internal passages to cool said body and the associated central processing unit or microprocessor.

2. A heat sink as defined in claim 1, wherein said body is formed from a material having a high coefficient of thermal conductivity.

3. A heat sink as defined in claim 2, wherein the material is a metal capable of being machined, namely aluminum.

4. A heat sink as defined in claim 1, wherein said body has a plurality of passages extending in a first direction and a plurality of passages extending in a second direction substantially transverse to the first direction.

5. A heat sink as defined in claim 4, wherein said passages in respectively the first and second directions intersect each other, whereby they open out into each other.

6. A heat sink as defined in claim 5, wherein the ends of the passages at the outer surface of said body also open out onto the outer surface of said body, whereby they facilitate the passage of air from the outside into the internal passages.

7. A heat sink as defined in claim 4, wherein the passages have a broadly circular cross-section with a diameter of approximately 3 to 6 mm, and the passages extend substantially from one side of said body to the other side of said body.

8. A heat sink as defined in claim 7, wherein said body is in the form of a block having a broadly rectangular configuration, and wherein the passages extending in the first direction extend between two opposed sides that are parallel, and wherein the passages extending in the second direction extend between a further two parallel opposed sides that are substantially orthogonal to the first pair of opposed sides.

9. A heat sink as defined in claim 4, wherein the passages extending in the first direction are arranged in the form of an array or matrix when viewed end on.

10. A heat sink as defined in claim 9, wherein there is an array of at least approximately 64 passages extending in said first direction, and an array of at least approximately 64 passages extending in said second direction.

11. A heat sink as defined in claim 4, wherein said body also defines at least one void therein which is free of body material and through which air is free to flow.

12. A heat sink as defined in claim 11, wherein each void extends from a leading face of said outer surface of the body into said body in one of the first or second directions, and each void extends at least half of the length of said body in said first or second direction.

13. A heat sink as defined in claim 12, wherein each void defines an elongate slot that opens onto said leading face of the outer surface, and wherein said fan is mounted over said leading face whereby to blow air through said voids.

14. A heat sink as defined in claim 13, wherein each slot has a cross-sectional configuration on said leading face of the outer surface wherein the slot extends substantially fully between opposed sides of said leading face, and the slot has a width of approximately 4 to 13 mm at least part of the way along its length.

15. A heat sink as defined in claim 14, wherein said body defines two said voids that are slots that extend at an angle to each other and that also intersect each other.

16. A heat sink as defined in claim 15, wherein the slots extend substantially perpendicularly to each other and form a cross when viewed end on.

17. A heat sink as defined in claim 16, wherein one said slot extends diagonally across the face of the body from one corner to a diagonally opposed corner, and the other said slot extends substantially diagonally across the face of the slot from another corner to its diagonally opposed corner.

18. A heat sink as defined in claim 1, wherein the fan is a low velocity fan having a speed of from approximately 2,000 to 5,000 rpm so as to reduce noise generated by the fan.

19. A heat sink as defined in claim 1, wherein said body is formed from a single piece of metal and the internal passages defined in the body are machined into the body using a computer numerical control (CNC) machine.

20. A heat sink as defined in claim 1, additionally comprising a microprocessor in combination with the heat sink.

21. A heat sink as defined in claim 20, wherein said body has a plurality of passages extending in a first direction and a plurality of passages extending in a second direction substantially transverse to the first direction.

22. A heat sink as defined in claim 1, additionally comprising a computer including a central processing unit in combination with the heat sink.

23. A heat sink for use with a central processing unit or microprocessor, the heat sink comprising:
a body having a top surface, a bottom surface, and four side surfaces, said bottom surface of said body for placement onto the central processing unit or processor;
a first plurality of internal passages extending between two non-adjacent sides of said body;
a second plurality of internal passages located orthogonal to said first plurality of internal passages, said second plurality of internal passages extending from said top surface of said body toward said bottom surface of said body, said first and second pluralities of internal passages being in fluid communication with each other, said first and second pluralities of internal passages defining an internal surface; and
a fan mounted on said top surface of said body to displace air over the internal surface of said body, whereby heat is transferred from said body to air passing through said first and second pluralities of internal passages to cool said body and a central processing unit or microprocessor upon which said bottom surface of said body is placed.

24. A method of making a heat sink for use with a central processing unit or microprocessor, the method comprising:
forming an internal surface in a body having an outer surface facing the exterior, said interior surface comprising a plurality of internal passages defined in said body; and
mounting a fan on said body to displace air over the internal surface of said body, whereby heat is transferred from said body to air passing through said internal passages to cool said body and the associated central processing unit or microprocessor.
